(19) United States
(12) Patent Application Publication
(10) Pub. No.: US 2024/0425353 A1
(43) Pub. Date: Dec. 26, 2024

(54) ACOUSTIC SENSOR DEVICE WITH MULTI-SIDED ANCHOR

(71) Applicant: Soundskrit Inc., Montreal (CA)

(72) Inventors: Stephane Leahy, Montreal (CA); Wan-Thai Hsu, Saline, MI (US)

(21) Appl. No.: 18/752,164

(22) Filed: Jun. 24, 2024

Related U.S. Application Data
(60) Provisional application No. 63/522,607, filed on Jun. 22, 2023.

(51) Int. Cl. B81B 3/00; H04R 1/08

(52) U.S. Cl. CPC B81B 3/0021; B81B 2201/0257; B81B 2203/0118; B81B 2203/0127; B81B 2203/0136; B81B 2203/0353; H04R 1/08; H04R 2201/003

(57) ABSTRACT

An acoustic sensor device includes a substrate, a cavity formed in the substrate, and a microelectromechanical system (MEMS) transducer having a diaphragm supported by the substrate. The diaphragm includes a first portion configured to be fixed to the substrate and a second portion extending from the first portion and suspended over the cavity. The second portion is configured to vibrate when the MEMS transducer is subject to an external stimulus. The diaphragm also includes an anchor portion that attaches the first portion of the diaphragm to the substrate on at least two sides of the substrate such that an interface between the first portion of the diaphragm and the second portion of the diaphragm is moved away from an edge of the substrate along the cavity.

### CROSS-REFERENCES TO RELATED APPLICATIONS

This application claims the benefit of U.S. provisional application entitled “MEMS Microphone with Multi-Sided Anchor,” filed Jun. 22, 2023, and assigned Ser. No. 63/522,607, the entire disclosure of which is hereby expressly incorporated by reference.

### BACKGROUND OF THE DISCLOSURE

### Field of the Disclosure

The disclosure relates generally to acoustic sensor devices that as microelectromechanical system (MEMS) microphones.

### Brief Description of Related Technology

A typical acoustic sensor device, such as a typical MEMS microphone, includes a transducer having a diaphragm, or other movable element, supported by a substrate having a cavity. The diaphragm, or other movable element, may be attached to the substrate through an insulator layer that may be provided on a surface between the diaphragm and the substrate. The diaphragm may include a first portion that is anchored on, or supported by, the substrate and a second portion that extends outwards from the first portion over the cavity. Because the first portion of the diaphragm is anchored to the substrate, the first portion of the diaphragm is fixed and does not move when the diaphragm is exposed to external stimulus, such as air flow or pressure caused by a sound wave. On the other hand, the second portion of the diaphragm is suspended over the cavity and will vibrate when exposed to the same external stimulus. The transducer may transduce the vibration of the diaphragm into an electrical signal. Movement of the second portion of the diaphragm may cause deflection and bending of the diaphragm at an interface between the first, fixed, portion of the diaphragm and the second, movable, portion of the diaphragm in response to the movement of the second portion of the diaphragm. When the interface between the first, fixed, portion of the diaphragm and the second, movable, portion of the diaphragm is aligned with or otherwise coincides with an edge of the substrate along the cavity, the deflection of the diaphragm at the interface may damage the diaphragm. Deflection of the diaphragm at the interface may cause cracking or breaking of the diaphragm as the diaphragm bends over the of the edge the substrate along the cavity, which may, in some cases, be jagged or otherwise rough or uneven.

Some diaphragms, or other movable elements, of acoustic sensor devices, include plate-shaped structures with holes creating a porous plate-shaped cantilever structure. Such porous plate-shaped cantilever structures may experience stress due to an abrupt increase in porosity as the cantilever structure extends outwards from a substrate and over a cavity.

### SUMMARY OF THE DISCLOSURE

In accordance with one aspect of the disclosure, an acoustic sensor device comprises a substrate, a cavity formed in the substrate, and a microelectromechanical system (MEMS) transducer having a diaphragm supported by the substrate. The diaphragm includes a first portion configured to be fixed to the substrate, a second portion extending from the first portion and suspended over the cavity, the second portion configured to vibrate when the MEMS transducer is subject to an external stimulus, and an anchor portion that attaches the first portion of the diaphragm to the substrate on at least two sides of the substrate such that an interface between the first portion of the diaphragm and the second portion of the diaphragm is moved away from an edge of the substrate along the cavity.

In accordance with another aspect of the disclosure, an acoustic sensor device comprises a substrate, a cavity formed in the substrate, and a microelectromechanical system (MEMS) transducer supported by the substrate. The MEMS transducer includes a diaphragm including a first portion configured to be fixed to the substrate on at least one side of the substrate and a second portion extending from the first portion and suspended over the cavity, the second portion configured to vibrate when subject to external stimulus. The diaphragm comprises a plate having a plurality of holes distributed over a surface of the plate. The plurality of holes the plurality of holes includes a first set of holes distributed in the second portion of the diaphragm, and one or more additional sets of holes disposed on the surface of the plate closer to an interface between the first portion of the diaphragm and the second portion of the diaphragm as compared holes in the first set of holes, and wherein the one or more additional sets of holes include holes that are different from holes in the first set of holes.

In connection with any one of the aforementioned aspects, the acoustic sensor devices described herein may alternatively or additionally include or involve any suitable combination of one or more of the following aspects or features.

The substrate comprises an insulator layer disposed on a surface of the substrate. The first portion of the diaphragm is attached to the substrate through the insulator layer. The cavity formed in the substrate includes a portion that extends into the insulator layer, forming an undercut in the insulator layer between the diaphragm and the substrate. The anchor portion is configured to attach the first portion of the diaphragm to the substrate on at least two sides such that the interface between the first portion of the diaphragm and the second portion of the diaphragm is moved away from an edge of the undercut in the insulator layer. The anchor portion is configured to attach the first portion of the diaphragm to the substrate on a first sides of the substrate and a second side of the substrate, wherein the first side of the substrate and the second side of the substrate are opposing sides of the substrate that are separated by a third side of the substrate. The anchor portion is configured to attached the first portion of the diaphragm to the substrate further along the third side of the substrate. The anchor portion of the diaphragm includes an anchor extension portion that extends along at least one side of the substrate over a length of the cavity along the at least one side of the substrate in direction of extension of the diaphragm from the substrate over the cavity. The anchor extension portion is configured to reduce an air gap along the at least one side between the substrate and the diaphragm. The diaphragm includes a stress reduction component at the interface between the first portion of the diaphragm and the second portion of the diaphragm at a proximal end of the anchor extension portion. The stress reduction component is configured to reduce stress gradient in the diaphragm along the anchor portion. The stress reduction component comprises a curved fillet. The diaphragm comprises a plate having a plurality of holes distributed over a surface of the plate. The plurality of holes comprises a first set of holes distributed in a first region on the surface of the plate, the first set of holes comprising holes of a first size, and a second set of holes distributed in a second region on the surface of the plate, wherein the second region on the surface of the plate is disposed closer to the interface between the first portion of the diaphragm and the second portion of the diaphragm as compared to the first region, and wherein the second set of holes comprises holes of a second size that is smaller than the first size. The plurality of holes further comprises a third set of holes distributed in a third region on the surface of the plate, wherein the third region is disposed between the first region and the second region, and wherein the third set of holes comprises holes of a third size that is larger than the second size but smaller than the first size. The first set of holes comprises holes distributed in a first region on the surface of the plate, the first set of holes comprising holes of a first size, and the one or more additional sets of holes comprises a second set of holes distributed in a second region on the surface of the plate, wherein the second region on the surface of the plate is disposed closer to the interface between the first portion of the diaphragm and the second portion of the diaphragm as compared to the first region, and wherein the second set of holes comprises holes of a second size that is smaller than the first size. The first set of holes comprises holes of a first diameter. The second set of holes comprises holes of a second diameter smaller than the first diameter. The one or more additional sets of holes further include a third set of holes distributed in a third region on the surface of the plate, wherein the third region is disposed between the first region and the second region, and wherein the third set of holes comprises holes of a third size that is larger than the second size and smaller than the first size. The diaphragm further comprises an anchor portion that attaches the first portion of the diaphragm to the substrate on at least two sides of the substrate such that an interface between the first portion of the diaphragm and the second portion of the diaphragm is moved away from an edge of substrate along the cavity.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 is a cross-sectional view of the working principle of a MEMS transducer in accordance with one example.

FIG. 2 is a cross-sectional view of a MEMS transducer in accordance with one example.

FIG. 3 depicts a top view of a transducer with a cantilevered diaphragm in accordance with one example.

FIG. 4 depicts a top view of a transducer with a cantilevered diaphragm in accordance with another example.

FIG. 5 depicts a top view of a transducer with a cantilevered diaphragm in accordance with still another example.

FIG. 6 depicts a top view of a transducer with a cantilevered diaphragm in accordance with yet another example.

FIG. 7 depicts a top view of a transducer with a cantilevered diaphragm in accordance with still another example.

FIG. 8 depicts a transducer that includes a plate-shaped diaphragm with multiple plates in accordance with one example.

FIG. 9 depicts a transducer that includes a plate-shaped diaphragm with multiple cavities in accordance with one example.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Acoustic sensor devices, such as MEMS microphones, with diaphragms or other movable elements anchored on multiple sides are described. The anchor of the disclosed microphones may accordingly be characterized as being multi-sided or multi-directional. Anchoring the diaphragm or other movable element of the microphone along multiple sides and/or in multiple directions may, for example, avoid deflection of the diaphragm at or near a jagged and/or otherwise rough or uneven edge along a cavity in or at which the diaphragm is disposed. Additionally, acoustic sensor devices, such as MEMS microphones, with diaphragms or other movable elements having a gradual increase in porosity as the diaphragm or other movable element extends over a cavity are described. The gradual increase in porosity may result in a reduced stress on the diaphragm, for example.

In an example, an acoustic sensor device includes a substrate, a cavity formed in the substrate, and a transducer (e.g., a MEMS transducer) having a diaphragm supported by the substrate. The diaphragm includes a first portion configured to be fixed to the substrate and a second portion extending from the first portion and suspended over the cavity. Because the first portion is fixed to the substrate, the first portion generally exhibits no or little movement when the MEMS transducer is exposed to an external stimulus, such as air flow or pressure caused by a sound wave. The second portion, on the other hand, is free vibrate when the MEMS transducer is subject to the same external stimulus. The diaphragm also includes an anchor portion that attaches the first portion of the diaphragm to the substrate on at least two sides of the substrate such that an interface between the first portion of the diaphragm and the second portion of the diaphragm is moved away from an edge of the substrate along the cavity.

In an aspect, moving the interface between the first portion of the diaphragm and the second portion of the diaphragm away from the edge of the substrate along the cavity eliminates or minimizes deflection of the diaphragm at or near the edge along the cavity, ensuring that there is no or little bending of the diaphragm over the edge along the cavity. In an example, at least a portion of the edge along the cavity may be jagged and/or otherwise rough or uneven as a result, for example, of the etching process used to create the cavity. In at least some examples, moving the interface between the first portion of the diaphragm and the second portion of the diaphragm away from the edge may prevent damage that may be caused to the diaphragm in configurations in which the diaphragm is not anchored on multiple sides and is, therefore, allowed to bend over the edge, particularly in cases of a jagged and/or otherwise rough or uneven edge.

As an example, the substrate may comprise an insulator layer disposed on a surface via which the diaphragm is attached to the substrate. Etching process that creates the cavity in the substrate may result in the cavity extending into the insulator layer under the diaphragm, creating an undercut that may have a jagged and/or otherwise rough or uneven edge in the insulator layer. In an aspect, the anchor portion of the diaphragm attaches the diaphragm to the substrate on multiple sides, thereby moving the interface between the first portion of the diaphragm and the second portion of the diaphragm away from the jagged and/or otherwise rough or uneven edge in the insulator layer along the cavity to reduce or eliminate bending of the diaphragm over the jagged and/or otherwise rough or uneven edge in the insulator layer along the cavity. This may prevent damage that may be caused to a diaphragm in a configuration in which the diaphragm is allowed to bend over the jagged and/or otherwise rough or uneven edge in the insulator layer along the cavity.

In some aspects, the anchor portion of the diaphragm may be elongated or otherwise extended to reach the multiple sides. The extent to which the anchor portion extends along any one of the sides may vary. For instance, the anchor portion may extend the entire length of one side, and only partially along one or more other sides. In still other cases, the structure of the anchor portion may be elongated or otherwise extend along one or more sides, and include a notch to allow for deflection of the movable element along the respective side. Such extension of the anchor structure may be useful in connection with minimizing or otherwise reducing the amount of space through which air may pass through the microphone while bypassing (e.g., without acting upon) the movable element. The notch may be terminated, configured, or otherwise shaped to facilitate fabrication.

Although generally described herein in connection with rectilinear examples having anchoring along three sides (or in three directions), the positioning, shape, extent, and other characteristics of the anchors may vary (e.g., in connection with the shape or configuration of the movable element). For instance, fewer or additional sides may be anchored. In some cases, the movable element is anchored along three sides. In other cases, the movable element is anchored along two sides (e.g., opposite sides). Further, although generally described herein in connection with moving an interface between a first, fixed, portion of a diaphragm and a second, movable, portion of the diaphragm away from an edge of an undercut in an insulator layer disposed on a substrate, the multi-sided (or multi-directional) anchoring may be used to move an interface between a first, fixed, portion of a diaphragm and a second, movable, portion of the diaphragm away from an edge of the substrate other than an edge of an undercut in an insulator layer disposed on the substrate.

In some aspects, an acoustic sensor device may include a diaphragm or other movable element that has a structure of a porous plate structure that extends over a cavity and is configured such that the amount of porosity per area of the diaphragm or other movable element gradually increases as the plate structure extends form a substrate and over the cavity. In an example, the acoustic sensor device may include a substrate, a cavity formed in the substrate, and a transducer (e.g., a MEMS transducer) having a porous diaphragm supported by the substrate. The diaphragm may include a first portion configured to be fixed to the substrate and a second portion extending from the first portion and suspended over the cavity. Because the first portion is fixed to the substrate, the first portion generally exhibits no or little movement when the transducer is exposed to an external stimulus, such as air flow or pressure caused by a sound wave. The second portion, on the other hand, is configured to vibrate when the transducer is subject to the external stimulus. The diaphragm includes a set of holes distributed across a surface of the diaphragm in the second portion that is suspended over the cavity. The diaphragm also includes one or more additional sets of holes relatively closer to the interface between the first portion and the second portion as compared to the set of holes in the second portion. The one or more additional sets of holes closer to the interface between the first portion and the second portion may have an arrangement and/or configuration different than the holes in the second portion. For example, the one or more additional sets of holes may be configured and/or arranged such that there is a gradual increase in the size (e.g., diameter) of the holes across the diaphragm as the diaphragm extend over the cavity. Accordingly, the amount of porosity per area of the diaphragm may increase when extending from the first portion to the second portion. This may result in more controlled and desired resting deflection after fabrication of the transducer. This may also reduce stress experienced by the diaphragm as the second portion of the diaphragm vibrates when subjected to the external stimulus.

The disclosed sensor devices having diaphragms or other movable elements anchored on multiple sides and/or diaphragms or other movable elements with gradual increase in porosity may be useful in a wide variety of microphone applications and contexts, including, for instance, various consumer devices such as smartphones, laptops, and earbuds that include or are otherwise equipped with microphones. Further, although generally described in connection with microphones, the disclosed sensor devices with diaphragms or other movable elements anchored on multiple sides may be used in other applications and contexts. For instance, the disclosed sensor devices equipped with diaphragms or other movable elements anchored on multiple sides and/or diaphragms or other movable elements with gradual increase in porosity are useful in connection with accelerometers, gyroscopes, inertial sensors, pressure sensors, gas sensors, etc. The disclosed sensor devices with diaphragms or other movable elements anchored on multiple sides and/or diaphragms or other movable elements with gradual increase in porosity are described in the context of excitation by sound waves. However, alternative or additional stimuli may excite the diaphragms or other movable elements of the disclosed sensor devices in other contexts.

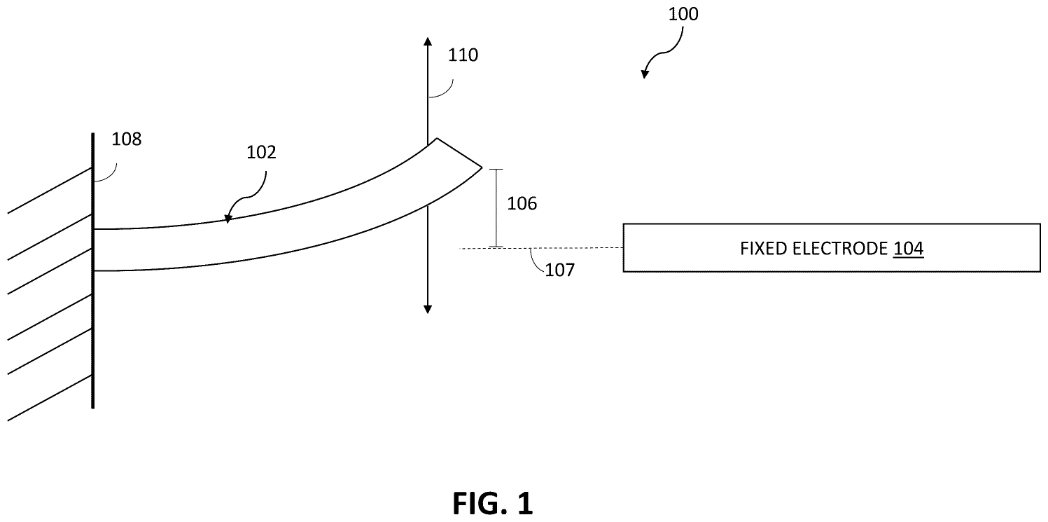

FIG. 1 is a cross-sectional (or side) view of the working principle of a transducer 100 in accordance with one example. The transducer 100 may be a MEMS transducer used in an acoustic sensor device, such as a microphone. The transducer 100 includes a movable element (also sometimes referred to herein as a movable electrode or a diaphragm) 102 and a fixed element (also sometimes referred to herein as a fixed electrode) 104. The movable element 102 is anchored on at least on side 108 and free to vibrate along axis or direction 110. The fixed electrode 104 is constructed such that the fixed electrode exhibits no, or reduced, motion along the direction 110 relative to movable electrode 102 when subject to the same external stimulus. Thus, the position of the movable element 102 along the direction 110 relative to the fixed electrode 104 changes in response to a sound wave along direction 110. The movable element 102 and fixed electrode 104 have at least one conductive layer each such that a capacitance is established between the movable element 102 and fixed electrode 104. The movable element 102 may be positioned to the side of the fixed electrode 104. The electrodes 102 and 104 may accordingly be referred to herein as side-by-side. In other examples, the MEMS transducer 100 may use suitable electrode configurations other than a side-by-side configuration.

The movable electrode 102 may have a resting warping or other deflection 106 relative to the midpoint 107 of the fixed electrode 104 in the direction of the movement 110. In the example of FIG. 1, the initial deflection is between a tip of the movable electrode 102 and the midpoint 107 of the fixed electrode 104. In some cases, the resting deflection may arise from warping of the movable electrode 102 during fabrication. When the transducer 100 is not subject to any sound and is at equilibrium, the movable electrode 102 is offset by deflection 106. The resting deflection may correspond with the position attained after application of a bias voltage, but without excitation by the medium. In some cases, the movable electrode 102 has an initial deflection 106 above the midpoint 107. In other cases, the movable electrode 102 has an initial deflection 106 below the midpoint 107. The initial deflection 106 may be greater than the height of the fixed electrode 104. In some examples, the initial deflection 106 may fall in a range from about 5 μm to about 50 μm, but other amounts may be used.

A capacitance is formed between the movable electrode 102 and the fixed electrode 104. As the movable electrode 102 experiences motion along the direction 110, the capacitance between the movable electrode 102 and fixed electrode 104 may change. As the movable electrode 102 approaches the fixed electrode 104 and midpoint 107, the capacitance increases. As the movable electrode 102 moves away from the fixed electrode 104 and midpoint 107, the capacitance decreases. The changes in capacitance between the movable electrode 102 and fixed electrode 104 can then be converted into an electronic signal that represents the motion of the movable electrode 102.

The initial deflection may be such that the distal portion of the movable electrode 102 does not reach or cross the fixed electrode 104 (e.g., the midpoint 107), or any other bias or sense electrode of the transducer, in the direction of the vibrational movement during operation in a linear regime of the measurement. In the example of FIG. 1, during operation in the linear regime, the tip of the movable electrode 102 does not cross the midpoint 107. In other words, the initial deflection 106 remains non-zero during operation of transducer 100. The linear regime may correspond with sound waves having certain one or more characteristics that fall within a certain range, including, for instance, a pressure (e.g., about 20 uPa to about 1 Pa) and a frequency (e.g., about 20 Hz to about 20 kHz). The specific ranges of sound waves that correspond to the linear regime may vary based on the transducer 100 and/or the application in which the transducer 100 is used. For instance, the transducer 100 may operate in the linear regime when subject to sound waves in typical acoustic environments (e.g., in a home, outside, in an office room, in a vehicle, etc.). Sound waves in a typical acoustic environment may include human speech, noise from a speaker or TV, noise from a vehicle, noise from home appliances, etc. In some scenarios where the transducer 100 is placed close to a loudspeaker (e.g., in a smart speaker, conference phone, TV, etc.), the linear regime may correspond to sound waves with a sound pressure level above 1 Pa. In some cases, the linear regime may correspond with sound waves having a frequency above 100 Hz or above 300 Hz. When the sound waves fall outside one or more of the above-identified ranges, then, in some cases, the transducer 100 may operate in a non-linear regime in which the movable electrode 102 reaches and/or crosses the fixed electrode 104. When the movable electrode 102 reaches and/or crosses the fixed electrode 104, distortion may be present in the output of the microphone. It may be acceptable for the transducer 100 to operate in a non-linear regime when subject to sound waves with a large sound pressure level. The initial deflection of the transducer 100 and corresponding bias voltage used are set such that the distortion of the transducer 100 when subject to loud sound pressures in minimized or otherwise reduced. For example, the transducer 100 may operate in a non-linear regime when subject to a sound wave with a sound pressure level of 10 Pa such that the output maintains a total harmonic distortion between 1%-5% or less.

The movable electrode 102 may be warped or initially deflected above or below the fixed electrode 104. For instance, the initial deflection may be either away from (positive) or toward (negative) a substrate by which the movable electrode 102 is supported along the direction 110. Each of the examples described herein may exhibit such positive or negative warping.

A fixed bias voltage may be placed on one of the electrodes 102 or 104. As the movable electrode 102 moves along direction 110, this may result in a change in the charge and/or voltage seen at the electrode 102 or 104 on which there is no bias voltage placed. In one example, a bias voltage is placed on the movable electrode 102 and the fixed electrode 104 is connected to a voltage amplifier that holds the charge on the fixed electrode 104 constant and amplifies the voltage change seen on the fixed electrode as the movable electrode 102 vibrates. The fixed electrode 104 may be instead connected to a charge amplifier that holds the voltage on the fixed electrode 104 constant and amplifies the charge change seen at on the fixed electrode as the movable electrode 102 vibrates. In another example, a bias voltage is placed on the fixed electrode 104 and the movable electrode 102 is connected to a voltage amplifier that holds the charge on the movable electrode 102 constant and amplifies the voltage change seen on it as the movable electrode 102 vibrates. The movable electrode 102 may be instead connected to a charge amplifier that holds the voltage on the movable electrode 102 constant and amplifies the charge change seen on the movable electrode 102 as the movable electrode 102 vibrates. The bias voltage used may have a positive or negative value. The bias voltage may further have a DC and/or an AC component. In some examples, as a bias voltage is placed on electrode 102 or 104, the initial deflection 106 may reflect the equilibrium position attained via application of the bias voltage (e.g., the deflection may increase or decrease relative to the fixed electrode 104). The initial deflection 106 experienced may thus be dependent on the amplitude of the bias voltage and/or mechanical properties of the electrodes 102 and 104.

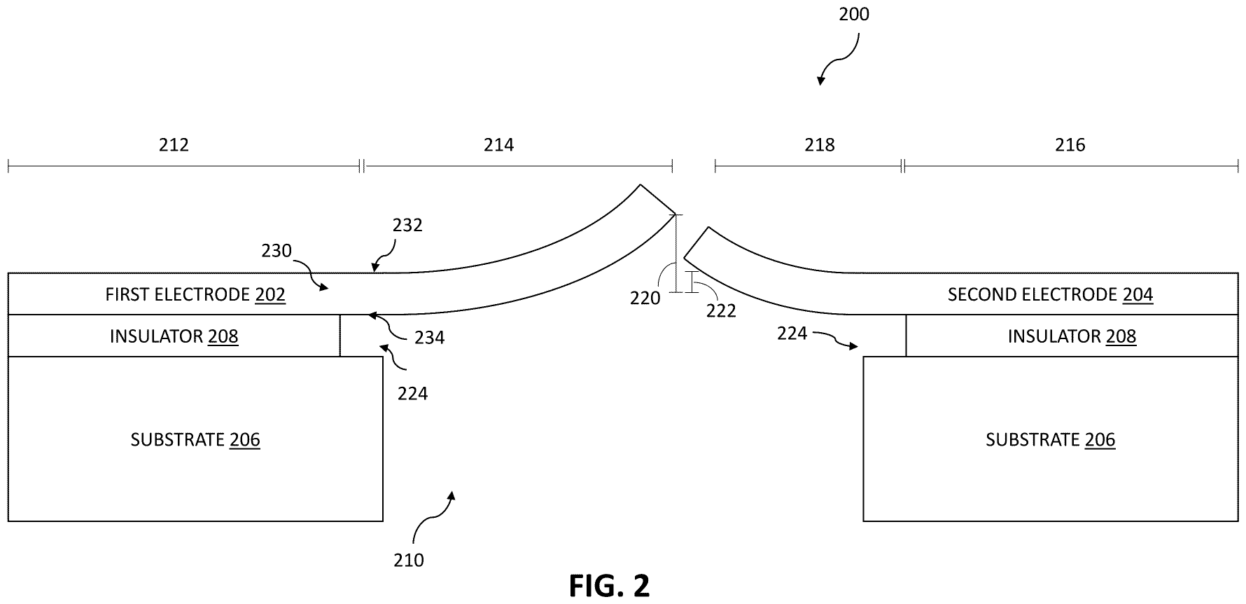

FIG. 2 depicts a cross-sectional view of a transducer 200 in accordance with one example. The transducer 200 may operate in a manner similar to the transducer 100 of FIG. 1, and the transducer 200 includes like-numbered elements with the transducer 100 of FIG. 1. Transducer 200 includes a first electrode 202 and second electrode 204 supported by a substrate 206 through insulator layer 208 (sometimes referred to herein as simply “insulator”) disposed on a surface of the substrate 206. The substrate 206 has a cavity 210. The first electrode 202 has a first portion 212 that is anchored, or supported by, the substrate 206 and a second portion 214 that extends outwards from the first portion 212. The second electrode 204 also has a first portion 216 that is anchored, or supported by, the substrate 206 and a second portion 218 that extends outwards from the first portion 216. The second portion 214 of the first electrode 202 has a resting deflection 220 relative to its first portion 212. The second portion 218 of the second electrode 204 has a resting deflection 222 relative to its first portion 216.

The length of the second portion 214 of the first electrode 202 may be greater than the length of the second portion 218 of the second electrode 204. Consequently, the resting deflection 220 may be greater than the resting deflection 222.

In some cases, after deep reactive ion etching (DRIE) is performed to form the cavity 210 in substrate 206, a portion of the insulator layer 208 may be etched away, creating an undercut 224 below the first electrode 202 and second electrode 204. This may be due to the deep reactive ion etch itself, or because the DRIE exposes the insulator 208 and makes it vulnerable to a proceeding etching step during the fabrication process. This undercut 224 defines the interface between the first portion 212 and second portion 214 of the first electrode 202, and the first portion 216 and second portion 218 of the second electrode 204.

As the transducer 200 is exposed to external stimulus such as air flow or pressure, the first electrode 202 will vibrate relative to the second electrode 204. Because the first portion 212 of the first electrode 202 is anchored to the substrate 206 through insulator 208, it will not move. However, the second portion 214 of the first electrode 202 is suspended over cavity 210 and will move up and down. The first electrode 202 may effectively bend at the interface between the first portion 212 and second portion 214 of the first electrode 202. If the first electrode 202 is attached to the substrate 206 through the insulator 208 on only one side of the substrate, such as only along a first side 230 the edge of the insulator 208 created by the undercut 224, then the interface between the first portion 212 and second portion 214 of the first electrode 202 is aligned with the edge of the insulator 208. In some instances, the undercut 224 may create a non-smooth edge at the insulator 208. As the first electrode 202 bends at this interface, the non-smooth edge of insulator 208 may cause unwanted stress or pressure on the first electrode 202 during operation. If the first electrode 202 undergoes large motion, the edge of insulator 208 may cause the first electrode 202 to crack or break. Thus, it is useful that the first electrode does not bend at interface between the edge of the insulator 208 and cavity 210, but rather remains relatively stiff or non-compliant. As described in more detail below, in some aspects, the first electrode 202 is anchored to the substrate 206 via a multi-sided anchor portion that anchors the first electrode 202 to the substrate 206 on multiple sides of the first electrode 202 (or of the substrate 206). In aspects, anchoring the first electrode 202 to the substrate 206 on multiple sides of the substrate 206 moves the interface between the first portion 212 and second portion 214 of the first electrode 202 away from the edge of the non-smooth edge of insulator 208, thereby preventing the damage that may be caused to the first electrode 202 by the edge of the insulator 208. In an example, the multi-sided anchor portion of the first electrode 202 may anchor the first electrode 202 to the substrate 206 on opposite sides 232, 234 of the substrate 206. The anchoring of the first electrode 202 to the substrate 206 on opposite sides 232, 234 may be in addition to, or instead of, anchoring the first electrode 202 to the substrate 206 on the first side 230 that is between the opposite sides 232, 234 and runs along the edge of the insulator 208. In other examples, the multi-sided anchor portion of the first electrode 202 may anchor the first electrode 202 to the substrate 206 on multiple sides of the first electrode 202 (or of the substrate 206) in other suitable configurations.

As described above, insulator 208 may include one or multiple layers including any combination of silicon, oxide, nitride, or a polymer. For example, insulator 208 may be composed of, or otherwise include a thermal oxide. In some examples, substrate 206 may be composed of, or otherwise include silicon. The non-smooth edge may be presented by additional or alternative layers, including non-insulating or conductive layers.

In the example of FIG. 2, the first electrode 202 and second electrode 204 may be configured as a composite layer. For example, the first electrode 202 and second electrode 204 may include multiple layers with at least one conductive layer. The first electrode 202 and second electrode 204 may include three layers where one or more of the layers is a conductive layer. The non-conductive layers may include any combination of silicon, oxide, nitride, or a polymer. The conductive layers may include any combination of silicon, doped silicon, polysilicon, amorphous silicon, or a metal such as aluminum, gold, or tungsten.

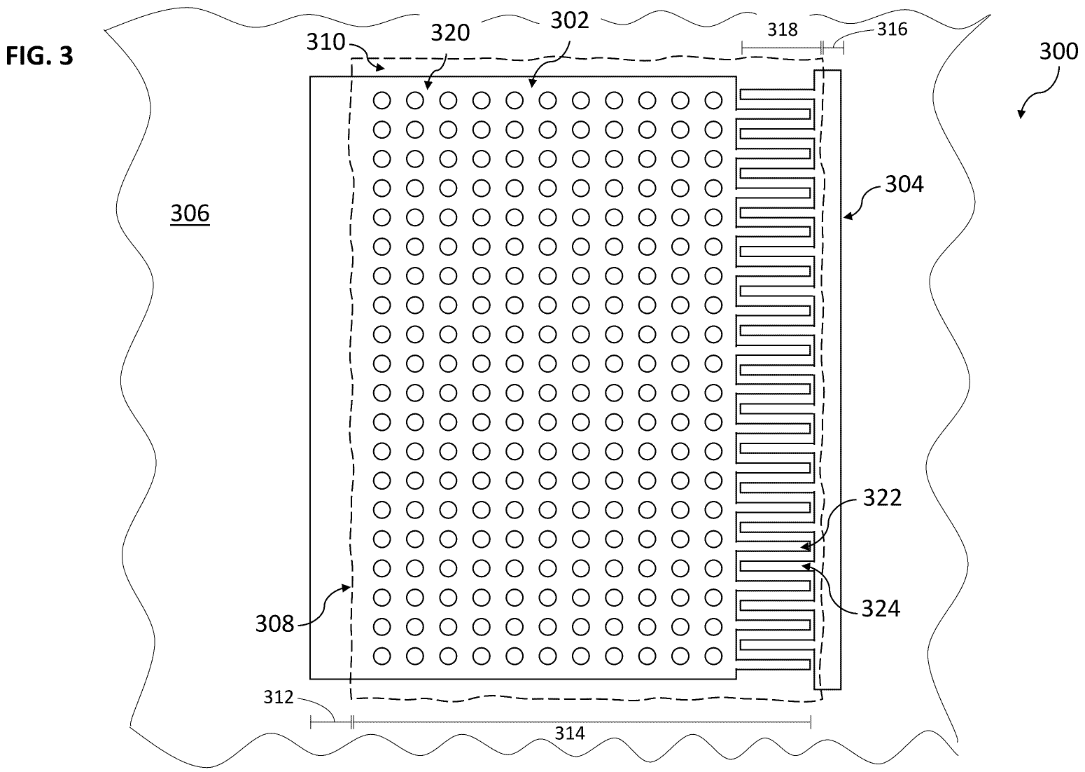

FIG. 3 depicts a top, schematic view of a transducer 300 with a diaphragm in accordance with one example. In this example, the diaphragm is cantilevered. In aspects, the transducer 300 may correspond to the transducer 200 of Figured 2, and the transducer 300 includes like-numbered elements with the transducer 200 of Figured 2. The transducer 300 includes a diaphragm, or first electrode, 302 that is attached to a surrounding substrate 306 on one end by a first portion 312. The substrate 306 has a cavity 310 above which the diaphragm 302 is positioned. The cavity 310 may be formed through various microfabrication practices, including, for instance, deep reactive ion etching (DRIE). The first electrode 302 sits side-by-side a second electrode 304. The second electrode 304 has a first portion 316 that is anchored to the substrate 306 and a second portion 318 that is suspended over the cavity 310. Due to the undercut as described in FIG. 2, the insulator between the first electrode 302 and substrate 306 has a non-smooth edge 308.

In an aspect, the first electrode 302 is or includes a diaphragm with a plate-shaped structure and holes 320. The holes have a spacing between them. In this manner, the diaphragm 302 may be configured as a porous plate. Attached to the edge of the second portion 314 of diaphragm 302 are one or more fingers 322. The fingers 322 are configured so that the fingers move with the diaphragm 302. The diaphragm 302 and fingers 322 may thus be considered a single or unitary composite movable structure, or electrode. The movable electrode includes at least one conductive layer.

The transducer 300 includes a fixed electrode 304 having fingers 324 fixed to the substrate 306. As the transducer 300 is excited by a sound wave, the fixed fingers 324 do not move, or move relatively less than fingers 322 to effectively be considered non-moving. Fingers 324 include at least one conductive layer such that a capacitance is formed between fingers 322 and 324. As diaphragm 302 vibrates, the gap between fingers 322 and 324 changes. This creates a change in capacitance between fingers 322 and 324 that is converted into an electronic signal as described in connection with the examples shown in other figures.

The transducer 300 may be configured such that the transducer has a first resonant frequency in the audio band. For example, the first resonant frequency of the transducer 300 may be in a range from about 1 kHz to about 5 kHz. Additionally, the transducer 300 may have a second resonant frequency that is close to the end of or outside of the audio band (e.g., greater than 16 kHz).

The diaphragm 302 is illustrated as a rectangle for ease of illustration. The diaphragm 302 may have a top profile that is rectangular, circular, elliptical, triangular, or any other geometrical shape. The cavity 310 may have a top profile that is rectangular, circular, elliptical, triangular, or any other geometrical shape. The fingers 322 may cover the entire perimeter of the free ends of the diaphragm 302 or one or more smaller subsections. The fingers 322 may have a thickness that is different than the thickness of diaphragm 302 and/or fingers 324. The fingers 322 and/or 324 may have a top profile that is rectangular, circular, elliptical, triangular, or any other geometrical shape. In some examples, the gap between the fingers 322 and 324 may fall in a range from about 1 μm to about 8 μm, the length of fingers 322 and 324 may fall in a range from about 50 μm to about 250 μm, and the width of fingers 322 and 324 may fall in a range from about 1 μm to about 20 μm. In other examples, the length and/or width of fingers 322 and/or 324 may vary relative to one another. For example, the fingers 322 and/or 324 on at least one of the free sides of diaphragm may have a different length than the remaining sides. In some examples, the gap of at least one set of fingers 322 and 324 along the perimeter of diaphragm 302 may be different than that of another set of fingers. In some examples, the diaphragm 302 may include two or more diaphragms that are coupled electrically and/or mechanically.

The first portion 312 of the diaphragm 302 is anchored to the substrate 306 on only one edge of the insulator 308, in the illustrated example. As the transducer 300 is exposed to external stimulus, the first electrode 302 will vibrate and bend at the edge of insulator 308 to which the diaphragm 302 is anchored. Because the edge of insulator 308 is non-smooth, it may cause unwanted stress or pressure on the diaphragm 302 during operation. If the first electrode 302 undergoes large motion, the edge of insulator 308 may cause the first electrode 302 to crack or break.

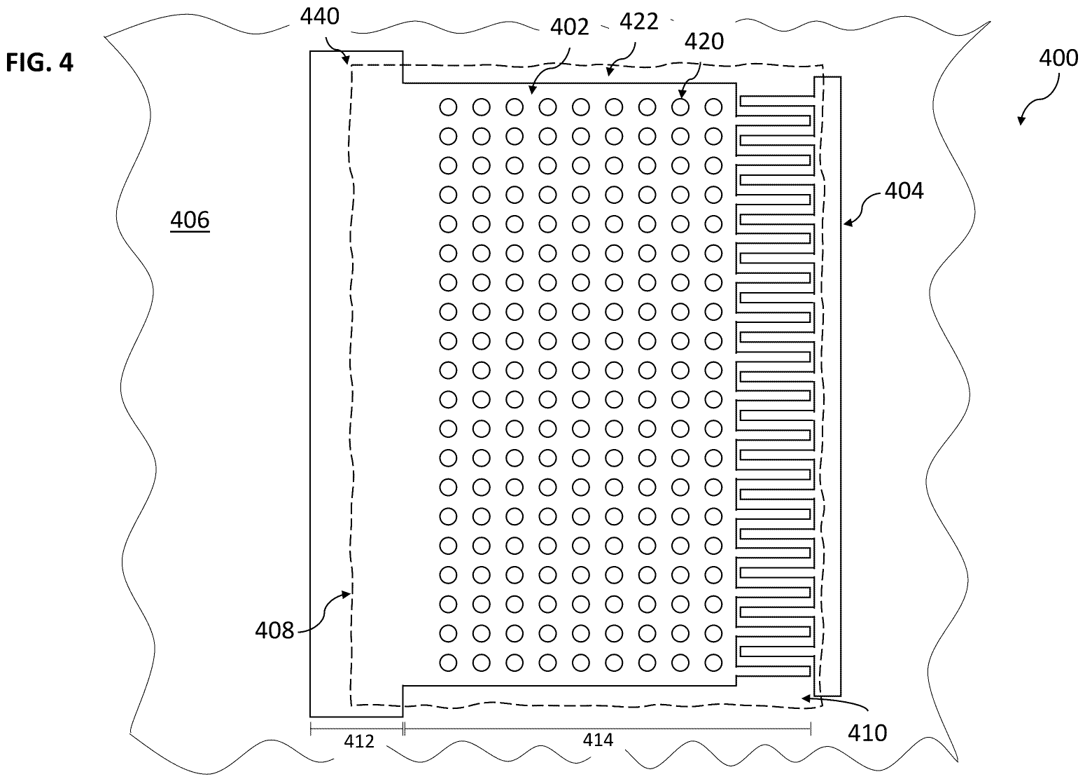

FIG. 4 depicts a top, schematic view of a transducer 400 with a cantilevered diaphragm, and having one or more like-numbered features or elements in common with transducer 300, but with a modified first portion in accordance with one example. The transducer 400 includes a diaphragm, or first electrode, 402 that is attached to a surrounding substrate 406 by a first portion 412. The substrate 406 has a cavity 410 above which the diaphragm 402 is positioned. The cavity 410 may be formed through various microfabrication practices, including, for instance, deep reactive ion etching (DRIE). The first electrode 402 sits side-by-side with a second electrode 404. Due to the undercut as described in FIG. 2, the insulator between the first electrode 402 and substrate 406 may have a non-smooth edge 408.

Unlike FIG. 3 where the first portion 312 of the diaphragm 302 is anchored to one side of the insulator edge 308, the first portion 412 of the diaphragm 402 is anchored on at least two different sides of the insulator edge 408. Because the first portion 412 of the diaphragm 302 is anchored on multiple sides, for example opposing sides, it is stiff (e.g., stiffer than the portion 414) and does not move significantly relative to the underlying layers or structures, or relative to the second portion 414 of the cantilever 402 when subject to external stimulus. When subject to external stimulus, the cantilever 402 bends at the interface between its first portion 412 and second portion 414. The interface is positioned over cavity 410 and offset of the leftmost side of the insulator edge 408. With this positioning, as the diaphragm 402 is excited by external stimulus, the diaphragm 402 may be capable of withstanding larger displacements before experiencing cracking or breaking.

The second portion 414 of the diaphragm 402 contains holes 420, creating a porous plate-shaped cantilever structure. However, the part of the first portion 412 of diaphragm 402 that is suspended over cavity 410 does not contain any holes. Thus, the transition from the first portion 412 to the second portion 414 of the diaphragm 402 may cause an abrupt change in internal stress in the diaphragm 402 and cause the plate to warp or have an undesired or non-smooth initial deflection.

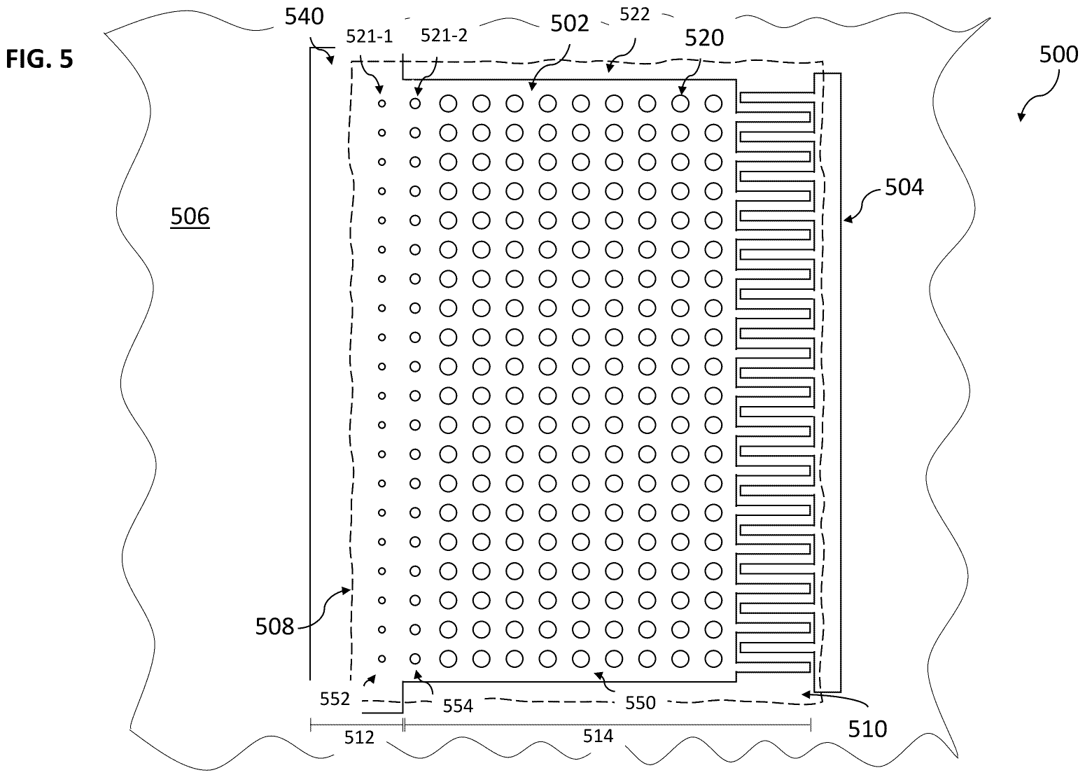

FIG. 5 depicts a top, schematic view of a transducer 500 with a diaphragm, and having one or more features or elements in common with the transducer 300 of FIG. 3 and/or the transducer 400 of FIG. 4, but with a diaphragm configured to have a more gradual transition in porosity in accordance with one example. The transducer 500 includes a diaphragm, or first electrode, 502 that is attached to a surrounding substrate 506 by a first portion 512. The substrate 506 has a cavity 510 above which the diaphragm 502 is positioned. The first electrode 502 sits side-by-side a second electrode 504, in the illustrated example. In some examples, due to the undercut as described in FIG. 2, the insulator between the first electrode 502 and substrate 506 has a non-smooth edge 508. In some examples, the transducer 500 includes a multi-sided anchor portion 540 that may be the same as or similar to the multi-sided anchor portion 440 of FIG. 4, or may be the same as or similar to anchor portions described in more detail below. In other examples, the transducer 500 may not include a multi-sided anchor portion. For example, the diaphragm of the transducer 500 may be anchored to the substrate 506 on only one side.

The diaphragm 502 includes a first set of holes 520. The first set of holes 520 may be distributed (e.g., as columns or rows, or in other suitable arrangements) in a first region 550 on the surface of the diaphragm 502, creating a porous plate-shaped structure. The first region 550 may be in the in the second portion 514 of the diaphragm 502. The diaphragm 502 also includes one or more additional sets of holes 521 distributed (e.g., as columns or rows, or in other suitable arrangements) in one or more additional regions that are relatively closer to the interface between the first portion 512 and the second portion 514 as compared to the first set of holes 120. The one or more additional sets of holes 521 include a second set of holes 521-1 and a third set of holes 521-2, in the illustrated example. The second set of holes 521-1 is distributed in a second region 552 at or close to the interface between the first portion 512 and the second portion 514. The third set of holes 521-2 is distributed in a third region 554 that is disposed between the second region 552 that includes the second set of holes 521-1 and the first region 550 that includes the set of holes 520. In other examples, the one or more additional sets of holes 521 may include more or fewer sets of holes 521. For example, the one or more additional sets of holes 521 may include three or more sets of holes that may be different from each other. In another example, the one or more additional sets of holes 521 may include only a single set of holes, such as only the second set of holes 521-1 or only the third set of holes 521-2.

In aspects, holes of the one or more additional sets of holes 521 have an arrangement and/or configuration different than holes of the first set of holes 520. In some instances, the holes of the one or more additional sets of holes 521 are smaller in size (e.g., diameter) than the holes of the first set of holes 520. For example, the one or more additional sets of holes may comprise holes that are smaller in diameter as compared to a diameter of holes of the first set of holes 520. In an example in which the one or more additional sets of holes 521 include multiple sets of holes 521, the multiple sets of holes 521 are arranged such that there is a gradual increase in the size (e.g., diameter) of holes as a function of proximity of the holes the set of holes 520, such that there is a gradual increase of the size of the holes across the diaphragm 502. Thus, for examples, the first set of holes 520 may comprise holes of a first size (e.g., first diameter), the second set of holes 521-1 may comprise holes of a second size (e.g., second diameter) that is smaller than the size (e.g., the first diameter), and the third set of holes 521-2 may comprise holes of a third size (e.g., third diameter) that is greater than the size (e.g., second diameter) but smaller that the first size (e.g., first diameter). As the diaphragm 502 extends from the first portion 512 to the second portion 514, the diaphragm 502 has a more gradual transition from a non-porous plate to a porous plate. In other words, the amount of porosity per area of the diaphragm 502 increases when extending from the first portion 512 to t second portion 514. This may result in more controlled and desired resting deflection after fabrication of the transducer 500. This may also reduce stress experienced by the diaphragm 502 as the second portion 514 of the diaphragm vibrates when subjected to an external stimulus.

In the example of transducers 400 and 500, a gap 422, 522 is present or defined between the second portion 414, 514 of the diaphragm 402, 502 and the edge of the insulator 408, 508. The gap 422, 522 may reduce the total acoustic force seen by the diaphragm 402, 502.

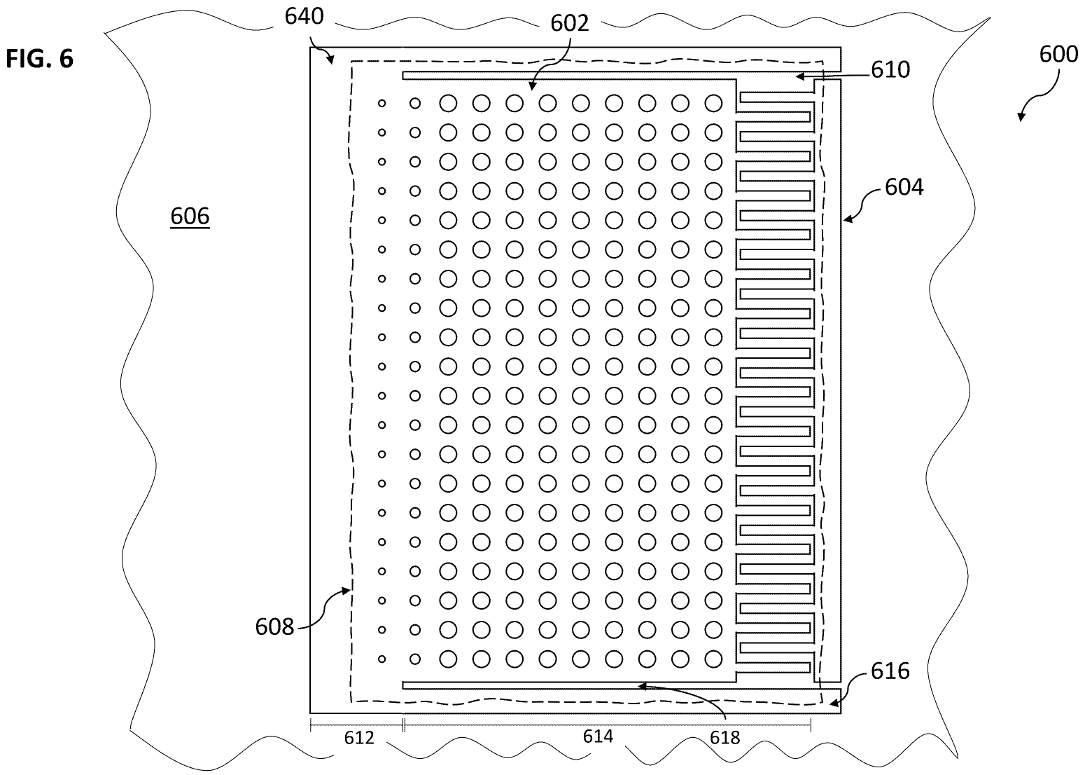

FIG. 6 depicts a top, schematic view of a transducer 600 with a diaphragm, and having one or more features or elements in common with the transducer 400 and/or the transducer 500, but with an anchor portion that extends along the length of the diaphragm in accordance with one example. The transducer 600 includes a diaphragm, or first electrode, 602 that is attached to a surrounding substrate 606 by a first portion 612. The substrate 606 has a cavity 610 above which the diaphragm 602 is positioned. The first electrode 602 sits side-by-side a second electrode 604. Due to the undercut as described in FIG. 2, the insulator between the first electrode 602 and substrate 606 has a non-smooth edge 608.

Transducer 600 has a second portion 614, which may have one or more aspects in common with the second portion of transducer 400 and/or the transducer 500. Alongside the second portion 614 of the diaphragm 602 that is free to move, there is an anchor extension portion 616 that in fixed to the substrate 606. In an example, the anchor extension portion 616 extends along at least one side of the substrate 606 over a length of the cavity 610, along the at least one side of the substrate 606 in a direction of extension of the diaphragm 602 from the substrate 606 over the cavity 610. The anchor extension portion 616 minimizes or otherwise reduces an air gap 618 between the diaphragm 602 and the edge of the cavity 610 at the substrate 606. As a result, the diaphragm 602 will see more acoustic force when subject to an acoustic wave and therefore provide a higher sensitivity.

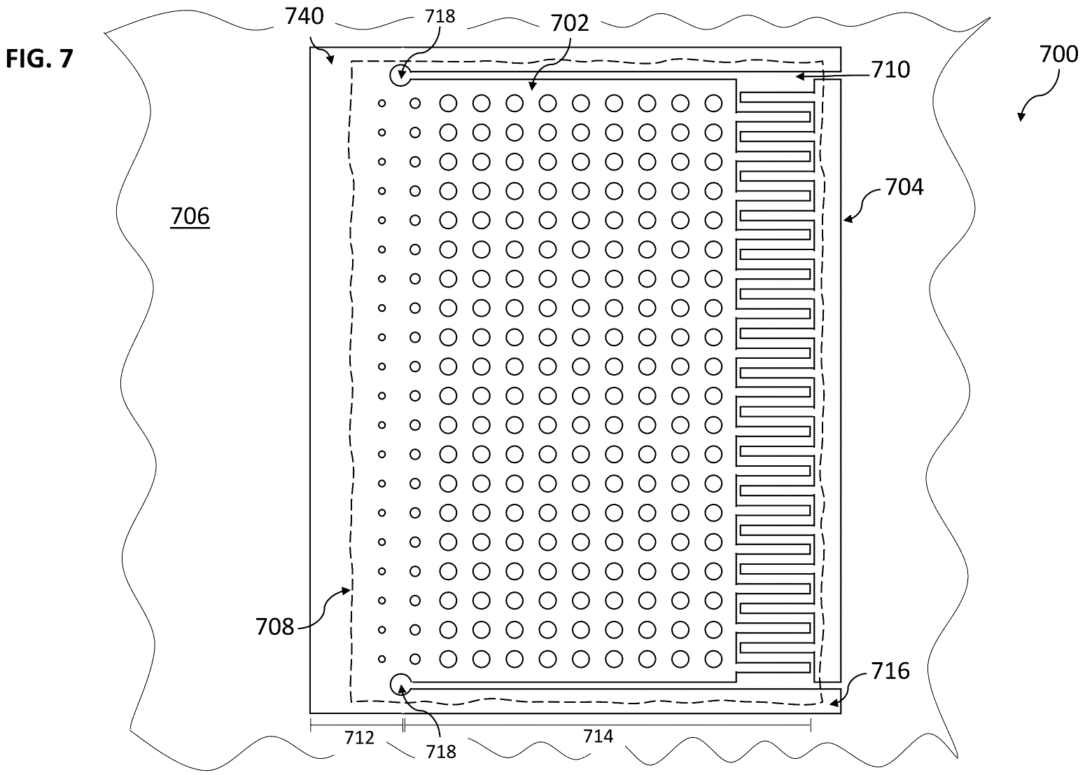

FIG. 7 depicts a top, schematic view of a transducer 700 with a diaphragm, and having one or more features or elements in common with the transducer 400, the transducer 500 and/or the transducer 600, but with an added feature in the anchor to reduce diaphragm stress during operation. The transducer 700 includes a diaphragm, or first electrode, 702 that is attached to a surrounding substrate 706 by a first portion 712. The substrate 706 has a cavity 710 above which the diaphragm 702 is positioned. The first electrode 702 sits side-by-side a second electrode 704. Due to the undercut as described in FIG. 2, the insulator between the first electrode 702 and substrate 706 has a non-smooth edge 708.

Transducer 700 has a second portion 714, having one or more aspects in common with the second portion of the other transducers described herein. Alongside the second portion 714 of the diaphragm 702 that is free to move, there is a portion of the anchor 716 that in fixed to the substrate 706. At the interface between the first portion 712 and second portion 714 of the diaphragm 702, there is a stress reduction component (e.g., a curved fillet) 718 at a proximal end of the anchor extension portion 716. The stress reduction component may create a smoother stress gradient in the diaphragm 702 along its anchor. As a result, as the diaphragm sees large displacements when subject to an acoustic wave, the diaphragm is less likely to crack or break from large internal stress gradients.

In some instances, it may be useful to increase the area of the transducer in order to increase the total capacitance of the sensor and thus performance.

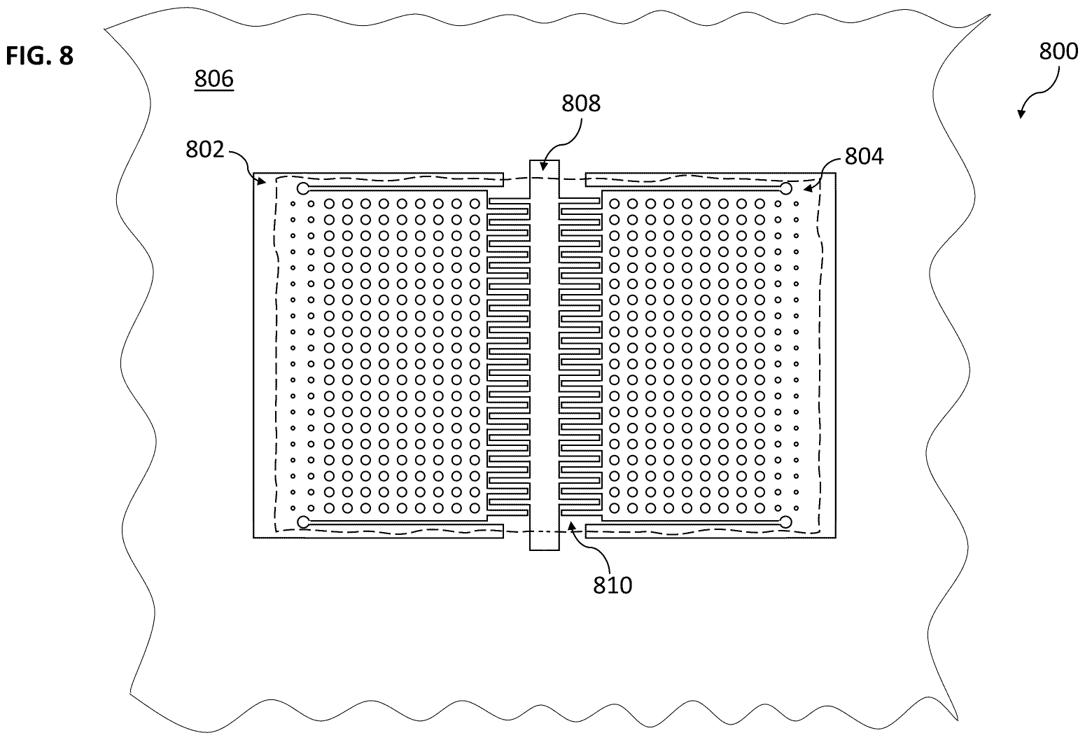

FIG. 8 depicts a transducer 800 including a plate-shaped diaphragm with an increased area in accordance with one example. Transducer 800 includes two plate-shaped diaphragms 802 and 804 that are attached to a common substrate 806. The diaphragms 802 and 804 have capacitive fingers that are interdigitated with fixed fingers attached to anchor 808 suspended over cavity 810. The plate-shaped diaphragms 802 and 804 may have one or more features or elements in common with those described in FIGS. 3-7. As the diaphragms 802 and 804 are excited by a sound wave, the diaphragms may move in phase with one another. Anchor 808 is constructed and otherwise configured such that the anchor does not move significantly relative to the motion of diaphragms 802 and 804 (e.g., effectively fixed or non-moving) when subject to the same external stimulus. The anchor 808 has fixed electrodes, or fingers, that also do not move significantly relative to the motion of diaphragms 802 and 804 when subject to the same external stimulus. As diaphragms 802 and 804 vibrate, the diaphragms create a change in capacitance with the fixed fingers of anchor 808. a way that diaphragms 1602 and 1604 move out-of-phase relative to one another. One or more bias voltages may be placed on diaphragms 802 and 804 and an electrical signal may be sensed from at least one conductive layer in anchor 808 that approximates the total capacitance change seen by transducer 800. By sensing the signal change from the suspended anchor 808, the parasitic capacitance between the sensing electrode and substrate 806 can be minimized. In another example, one or more bias voltages may be placed on one or more conductive layers of anchor 808. In this case, the total capacitance change seen by transducer 800 can be sensed by at least one conductive layer in 802 or 804. In some examples the diaphragms 802 and 804 may be electrically connected or held at the same voltage potential.

As the area of the MEMS transducer is increased, the area of the cavity etched into the substrate increases accordingly. In some instances, it may be useful to etch multiple, smaller cavities in the substrate rather than one larger cavity. This may also allow for the creation of transducers covering more area without an excessively long suspended structures such as fixed anchors.

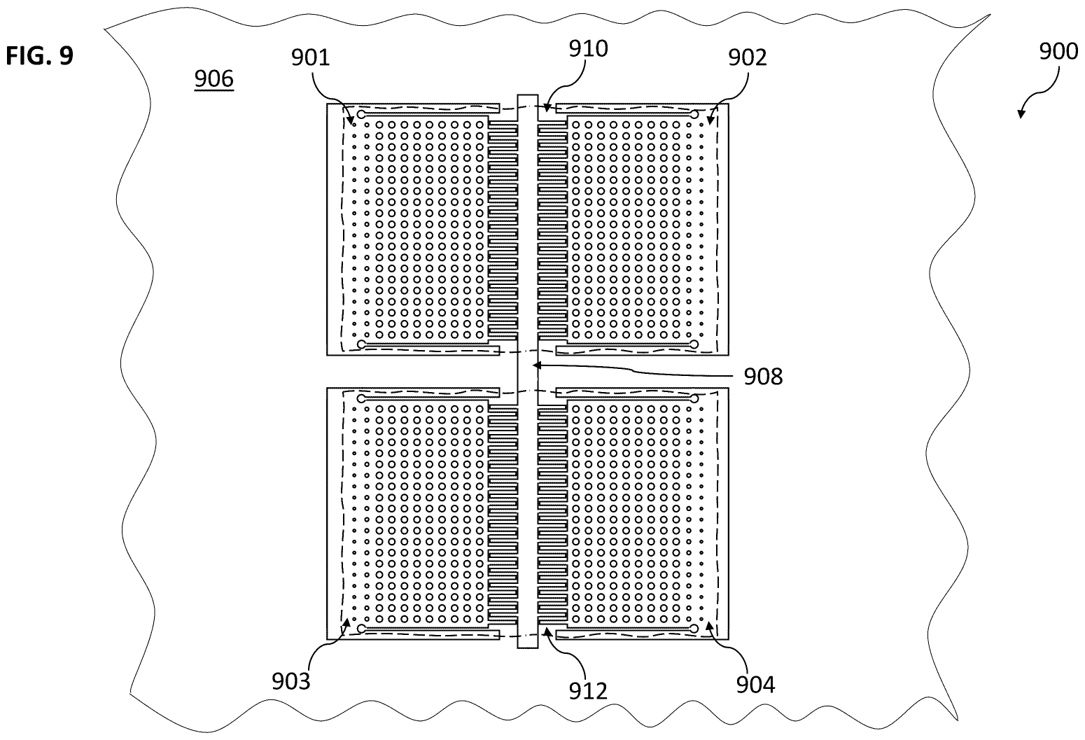

FIG. 9 depicts a transducer 900 that includes a plate-shaped diaphragm with multiple cavities in accordance with one example. Transducer 900 includes four plate-shaped diaphragms 901, 902, 903, and 904 connected to substrate 906. The plate-shaped diaphragms 901, 902, 903, and 904 may have one or more features or elements in common with those described in FIGS. 3-7. The transducer 900 includes a first cavity 910 through the substrate 906 over which diaphragms 901 and 902 are suspended and a second cavity 912 through the substrate 906 over which diaphragms 903 and 904 are suspended. The diaphragms 901, 902, 903, and 904, have interdigitated fingers with anchor 908. Anchor 908 has a first portion suspended over cavity 910 and a second portion suspended over cavity 912. When excited by the same external stimulus, the diaphragms 901, 902, 903, and 904 may move in phase with one another. The first portion and second portion of anchor 908, and the capacitive fingers thereof, do not move significantly relative to the diaphragms 901, 902, 903, and 904 (e.g., effectively fixed or non-moving) when subject to the same external stimulus as the first and second portion are each anchored to opposing sides of their respective cavity, making the first and second portions stiff relative to the plate-shaped diaphragms of transducer 900. As diaphragms 901, 902, 903, and 904 vibrate, the diaphragms create a change in capacitance with the fingers of anchor 908. In one example, diaphragms 901, 902, 903, and 904 may share the same conductive layers. An electrical signal may be sensed by any of the methods described in the previous examples.

Described above are a number of examples of acoustic sensor devices having diaphragms or other movable elements anchored on multiple sides and/or diaphragms or other movable elements with gradual increase in porosity. In an example, an acoustic sensor device includes a substrate, a cavity formed in the substrate, and a transducer (e.g., a MEMS transducer) having a diaphragm supported by the substrate. The diaphragm includes a first portion configured to be fixed to the substrate and a second portion extending from the first portion and suspended over the cavity. Because the first portion is fixed to the substrate, the first portion generally exhibits no or little movement when the MEMS transducer is exposed to an external stimulus, such as air flow or pressure caused by a sound wave. The second portion, on the other hand, is free vibrate when the MEMS transducer is subject to the same external stimulus. The diaphragm also includes an anchor portion that attaches the first portion of the diaphragm to the substrate on at least two sides of the substrate such that an interface between the first portion of the diaphragm and the second portion of the diaphragm is moved away from an edge of the substrate along the cavity.

In an aspect, moving the interface between the first portion of the diaphragm and the second portion of the diaphragm away from the edge of the substrate along the cavity eliminates or minimizes deflection of the diaphragm at or near the edge along the cavity, ensuring that there is no or little bending of the diaphragm over the edge along the cavity. In an example, at least a portion of the edge along the cavity may be jagged and/or otherwise rough or uneven as a result, for example, of the etching process used to create the cavity. In at least some examples, moving the interface between the first portion of the diaphragm and the second portion of the diaphragm away from the edge may prevent damage that may be caused to the diaphragm in configurations in which the diaphragm is not anchored on multiple sides and is, therefore, allowed to bend over the edge, particularly in cases of a jagged and/or otherwise rough or uneven edge.

In some aspects, an acoustic sensor device may include a diaphragm or other movable element that has a structure of a porous plate structure that extends over a cavity and is configured such that the amount of porosity per area of the diaphragm or other movable element gradually increases as the plate structure extends form a substrate and over the cavity. In an example, the acoustic sensor device may include a substrate, a cavity formed in the substrate, and a transducer (e.g., a MEMS transducer) having a porous diaphragm supported by the substrate. The diaphragm may include a first portion configured to be fixed to the substrate and a second portion extending from the first portion and suspended over the cavity. Because the first portion is fixed to the substrate, the first portion generally exhibits no or little movement when the transducer is exposed to an external stimulus, such as air flow or pressure caused by a sound wave. The second portion, on the other hand, is configured to vibrate when the transducer is subject to the external stimulus. The diaphragm includes a set of holes distributed across a surface of the diaphragm in the second portion that is suspended over the cavity. The diaphragm also includes one or more additional sets of holes relatively closer to the interface between the first portion and the second portion as compared to the set of holes in the second portion. The one or more additional sets of holes closer to the interface between the first portion and the second portion may have an arrangement and/or configuration different than the holes in the second portion. For example, the one or more additional sets of holes may be configured and/or arranged such that there is a gradual increase in the size (e.g., diameter) of the holes across the diaphragm as the diaphragm extend over the cavity. Accordingly, the amount of porosity per area of the diaphragm may increase when extending from the first portion to the second portion. This may result in more controlled and desired resting deflection after fabrication of the transducer. This may also reduce stress experienced by the diaphragm as the second portion of the diaphragm vibrates when subjected to the external stimulus.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. An acoustic sensor device, comprising:
a substrate;
a cavity formed in the substrate; and
a microelectromechanical system (MEMS) transducer having a diaphragm supported by the substrate, the diaphragm including
a first portion configured to be fixed to the substrate,
a second portion extending from the first portion and suspended over the cavity, the second portion configured to vibrate when the MEMS transducer is subject to an external stimulus, and
an anchor portion that attaches the first portion of the diaphragm to the substrate on at least two sides of the substrate such that an interface between the first portion of the diaphragm and the second portion of the diaphragm is moved away from an edge of the substrate along the cavity.

2. The acoustic sensor device of claim 1, wherein:
the substrate comprises an insulator layer disposed on a surface of the substrate;
the first portion of the diaphragm is attached to the substrate through the insulator layer; and
the cavity formed in the substrate includes a portion that extends into the insulator layer, forming an undercut in the insulator layer between the diaphragm and the substrate.

3. The acoustic sensor device of claim 2, wherein the anchor portion is configured to attach the first portion of the diaphragm to the substrate on at least two sides such that the interface between the first portion of the diaphragm and the second portion of the diaphragm is moved away from an edge of the undercut in the insulator layer.

4. The acoustic sensor device of claim 2, wherein the anchor portion is configured to attach the first portion of the diaphragm to the substrate on a first sides of the substrate and a second side of the substrate, wherein the first side of the substrate and the second side of the substrate are opposing sides of the substrate that are separated by a third side of the substrate.

5. The acoustic sensor device of claim 4, wherein the anchor portion is configured to attached the first portion of the diaphragm to the substrate further along the third side of the substrate.

6. The acoustic sensor device of claim 1, wherein the anchor portion of the diaphragm includes an anchor extension portion that extends along at least one side of the substrate over a length of the cavity along the at least one side of the substrate in a direction of extension of the diaphragm from the substrate over the cavity, the anchor extension portion configured to reduce an air gap along the at least one side between the substrate and the diaphragm.

7. The acoustic sensor device of claim 6, wherein the diaphragm includes a stress reduction component at the interface between the first portion of the diaphragm and the second portion of the diaphragm at a proximal end of the anchor extension portion, the stress reduction component configured to reduce stress gradient in the diaphragm along the anchor portion.

8. The acoustic sensor device of claim 7, wherein the stress reduction component comprises a curved fillet.

9. The acoustic sensor device of claim 1, wherein the diaphragm comprises a plate having a plurality of holes distributed over a surface of the plate.

10. The acoustic sensor device of claim 9, wherein the plurality of holes comprises:
a first set of holes distributed in a first region on the surface of the plate, the first set of holes comprising holes of a first size, and
a second set of holes distributed in a second region on the surface of the plate, wherein the second region on the surface of the plate is disposed closer to the interface between the first portion of the diaphragm and the second portion of the diaphragm as compared to the first region, and wherein the second set of holes comprises holes of a second size that is smaller than the first size.

11. The acoustic sensor device of claim 10, wherein the plurality of holes further comprises a third set of holes distributed in a third region on the surface of the plate, wherein the third region is disposed between the first region and the second region, and wherein the third set of holes comprises holes of a third size that is larger than the second size but smaller than the first size.

12. An acoustic sensor device, comprising:
a substrate;
a cavity formed in the substrate; and
a microelectromechanical system (MEMS) transducer supported by the substrate, the MEMS transducer having a diaphragm including
a first portion configured to be fixed to the substrate on at least one side of the substrate,
a second portion extending from the first portion and suspended over the cavity, the second portion configured to vibrate when subject to external stimulus,
wherein
the diaphragm comprises a plate having a plurality of holes distributed over a surface of the plate, and
the plurality of holes the plurality of holes includes
a first set of holes distributed in the second portion of the diaphragm, and
one or more additional sets of holes disposed on the surface of the plate closer to an interface between the first portion of the diaphragm and the second portion of the diaphragm as compared holes in the first set of holes, and wherein the one or more additional sets of holes include holes that are different from holes in the first set of holes.

13. The acoustic sensor device of claim 12, wherein:
the first set of holes comprises holes distributed in a first region on the surface of the plate, the first set of holes comprising holes of a first size, and
the one or more additional sets of holes comprises a second set of holes distributed in a second region on the surface of the plate, wherein the second region on the surface of the plate is disposed closer to the interface between the first portion of the diaphragm and the second portion of the diaphragm as compared to the first region, and wherein the second set of holes comprises holes of a second size that is smaller than the first size.

14. The acoustic sensor device of claim 13, wherein:
the first set of holes comprises holes of a first diameter; and
the second set of holes comprises holes of a second diameter smaller than the first diameter.

15. The acoustic sensor device of claim 13, wherein the one or more additional sets of holes further include a third set of holes distributed in a third region on the surface of the plate, wherein the third region is disposed between the first region and the second region, and wherein the third set of holes comprises holes of a third size that is larger than the second size and smaller than the first size.

16. The acoustic sensor device of claim 12, wherein the diaphragm further comprises an anchor portion that attaches the first portion of the diaphragm to the substrate on at least two sides of the substrate such that an interface between the first portion of the diaphragm and the second portion of the diaphragm is moved away from an edge of substrate along the cavity.

17. The acoustic sensor device of claim 16, wherein:
the substrate comprises an insulator layer on a surface of the substrate;
the first portion of the diaphragm is attached to the substrate through the insulator layer; and
the cavity formed in the substrate includes a portion that extends into the insulator layer, forming an undercut in the insulator layer between the diaphragm and the substrate.

18. The acoustic sensor device of claim 17, wherein the anchor portion is configured to attach the first portion of the diaphragm to the substrate such that the interface between the first portion of the diaphragm and the second portion of the diaphragm is moved away from an edge of the undercut in the insulator layer.

19. The acoustic sensor device of claim 16, wherein the anchor portion is configured to attach the first portion of the diaphragm to the substrate on a first sides of the substrate and a second side of the substrate, wherein the first side of the substrate and the second side of the substrate are opposing sides of the substrate that are separated by a third side of the substrate.

20. The acoustic sensor device of claim 19, wherein the anchor portion is further configured to attach the first portion of the diaphragm to the substrate further along the third side of the substrate.
